(19) United States
(12) Patent Application Publication
(10) Pub. No.: US 2023/0343705 A1
(43) Pub. Date: Oct. 26, 2023

(54) THREE-DIMENSIONAL MEMORY DEVICE AND MANUFACTURING METHOD THEREOF

(71) Applicant: SK hynix Inc., Icheon-si (KR)

(72) Inventor: Hyun Soo SHIN, Icheon-si (KR)

(21) Appl. No.: 17/896,329

(22) Filed: Aug. 26, 2022

(30) Foreign Application Priority Data
Apr. 25, 2022 (KR) 10-2022-0050828

(51) Int. Cl. H01L 23/528; H01L 27/11582; H01L 23/535

(52) U.S. Cl. CPC H01L 23/5283; H01L 23/535; H01L 27/11582

(57) ABSTRACT

A method for manufacturing a three-dimensional memory device includes forming a lower multi-layered stack by alternately stacking a plurality of first dielectric layers and a plurality of first sacrificial layers on a substrate; forming an etch stop layer on the lower multi-layered stack; forming an upper multi-layered stack by alternately stacking a plurality of second dielectric layers and a plurality of second sacrificial layers on the etch stop layer; forming a vertical trench by etching the upper multi-layered stack using the etch stop layer as an etch end target; removing the etch stop layer under the vertical trench; and forming a first stairway-shaped trench in the lower multi-layered stack under the vertical trench, and forming a second stairway-shaped trench in the upper multi-layered stack.

### CROSS-REFERENCE TO RELATED APPLICATION

The present application claims priority under 35 U.S.C. §119(a) to Korean Patent Application No. 10-2022-0050828 filed in the Korean Intellectual Property Office on Apr. 25, 2022, which is incorporated herein by reference in its entirety.

### BACKGROUND

### 1. Technical Field

Various embodiments generally relate to a semiconductor technology, and particularly, to a three-dimensional memory device and a manufacturing method thereof.

### 2. Related Art

A three-dimensional memory device has advantages in that a larger capacity may be realized within the same area by increasing the number of stacks through stacking memory cells in a vertical direction, thereby providing high performance and excellent power efficiency.

In the three-dimensional memory device, electrode layers coupled to the memory cells are disposed at different heights. In order to independently apply electrical signals to the electrode layers that are disposed at different heights in such devices, various technologies are being developed to couple contacts to each of the electrode layers.

### SUMMARY

Various embodiments are directed to a three-dimensional memory device and a manufacturing method thereof, capable of improving a process margin.

In an embodiment, a method for manufacturing a three-dimensional memory device may include: forming a lower multi-layered stack by alternately stacking a plurality of first dielectric layers and a plurality of first sacrificial layers on a substrate; forming an etch stop layer on the lower multi-layered stack; forming an upper multi-layered stack by alternately stacking a plurality of second dielectric layers and a plurality of second sacrificial layers on the etch stop layer; forming a vertical trench by etching the upper multi-layered stack using the etch stop layer as an etch end target; removing the etch stop layer under the vertical trench; and forming a first stairway-shaped trench in the lower multi-layered stack under the vertical trench, and forming a second stairway-shaped trench in the upper multi-layered stack.

In an embodiment, a three-dimensional memory device may include: a lower structure including a plurality of first dielectric layers and a plurality of first electrode layers that are alternately stacked on a substrate, and having an uppermost layer that is configured by one of the first electrode layers and has a thickness that is different from the thickness of an etch stop layer and the other underlying first electrode layers; an upper structure including a plurality of second dielectric layers and a plurality of second electrode layers which are alternately stacked on the lower structure; a vertical trench exposing the lower structure by passing through the upper structure; a first stairway-shaped trench configured in the lower structure under the vertical trench, that communicates with the vertical trench; and a second stairway-shaped trench configured in the upper structure.

In an embodiment, a method for manufacturing a three-dimensional memory device may include: forming a lower multi-layered stack by alternately stacking a plurality of first dielectric layers and a plurality of first sacrificial layers on a substrate; forming an etch stop layer on the lower multi-layered stack; forming an upper multi-layered stack by alternately stacking a plurality of second dielectric layers and a plurality of second sacrificial layers on the etch stop layer; forming a plurality of first vertical holes by etching the upper multi-layered stack using the etch stop layer as an etch end target; removing the etch stop layer under the plurality of first vertical holes; and forming a plurality of second vertical holes, which extend downward from the plurality of first vertical holes, in the lower multi-layered stack, and forming a plurality of third vertical holes in the upper multi-layered stack.

In an embodiment, a three-dimensional memory device may include: a lower structure including a plurality of first dielectric layers and a plurality of first electrode layers, which are alternately stacked on a substrate, and having an uppermost layer that is configured by one of the first electrode layers and has a thickness different from an etch stop layer and the other underlying first electrode layers; an upper structure including a plurality of second dielectric layers and a plurality of second electrode layers that are alternately stacked on the lower structure; a plurality of first vertical holes exposing the lower structure by passing through the upper structure; a plurality of second vertical holes, configured in the lower structure, that extend downward from the plurality of first vertical holes; and a plurality of third vertical holes configured in the upper structure.

### BRIEF DESCRIPTION OF THE DRAWINGS

FIG. 1 is a schematic top view of a three-dimensional memory device in accordance with an embodiment of the present disclosure.

FIGS. 2A and 2B are cross-sectional views illustrating a three-dimensional memory device in accordance with an embodiment of the present disclosure.

FIG. 3 is a flowchart illustrating a method for manufacturing a three-dimensional memory device in accordance with an embodiment of the present disclosure.

FIGS. 4A to 4G are cross-sectional views illustrating, by manufacturing steps, a three-dimensional memory device in accordance with an embodiment of the present disclosure.

FIGS. 5 to 7 are cross-sectional views illustrating three-dimensional memory devices in accordance with various embodiments of the present disclosure.

FIGS. 8A and 8B are cross-sectional views illustrating a three-dimensional memory device in accordance with an embodiment of the present disclosure.

FIG. 9 is a flowchart illustrating a method for manufacturing a three-dimensional memory device in accordance with an embodiment of the present disclosure.

FIGS. 10A to 10G are cross-sectional views illustrating, by manufacturing steps, a three-dimensional memory device in accordance with an embodiment of the present disclosure.

FIGS. 11 to 13 are cross-sectional views illustrating three-dimensional memory devices in accordance with various embodiments of the present disclosure.

FIG. 14 is a block diagram schematically illustrating a memory system including a three-dimensional memory device in accordance with embodiments of the present disclosure.

FIG. 15 is a block diagram schematically illustrating a computing system including a three-dimensional memory device in accordance with embodiments of the present disclosure.

### DETAILED DESCRIPTION

Advantages and features of the disclosure and methods to achieve them will become apparent from the descriptions of exemplary embodiments herein below and described with reference to the accompanying drawings. However, the present disclosure is not limited to the exemplary embodiments disclosed herein but may be implemented in various different ways. The exemplary embodiments of the present disclosure convey the scope of the disclosure to those skilled in the art.

The figures, dimensions, ratios, angles, numbers of elements given in the drawings that describe embodiments of the disclosure are merely illustrative and are not limiting. Throughout the specification, like reference numerals refer to like elements. In describing the disclosure, when it is determined that a detailed description of the known related art may obscure the gist or clarity of the disclosure, the detailed description thereof will be omitted. It is to be understood that the terms “comprising,” “having,” “including” and so on, used in the description and claims, should not be interpreted as being restricted to the means listed thereafter unless specifically stated otherwise. Where an indefinite or definite article is used when referring to a singular noun (e.g., “a,” “an,” “the”), the article may include a plural of that noun unless specifically stated otherwise. In interpreting elements in embodiments of the disclosure, they should be interpreted as including error margins even in the absence of explicit statements.

Also, in describing the components of the disclosure, there may be terms used like first, second, A, B, (a), and (b). These are solely for the purpose of differentiating one component from the other and do not to imply or suggest the substances, order, sequence or number of the components. Also, elements in embodiments of the disclosure are not limited by these terms. These terms are used to merely distinguish one element from another. Accordingly, as used herein, a first element may be a second element within the technical idea of the disclosure.

If a component is described as “connected,” “coupled” or “linked” to another component, it may mean that the component is not only directly “connected,” “coupled” or “linked” but also is indirectly “connected,” “coupled” or “linked” via a third component. In describing positional relationship, such as “an element A on an element B,” “an element A above an element B,” “an element A below an element B” and “an element A next to an element B,” another element C may be disposed between the elements A and B unless the term “directly” or “immediately” is explicitly used.

Features of various exemplary embodiments of the disclosure may be coupled, combined or separated partially or totally. Various interactions and operations are technically possible. Various exemplary embodiments can be practiced individually or in combination.

Hereinafter, various examples of embodiments of the disclosure will be described in detail with reference to the accompanying drawings.

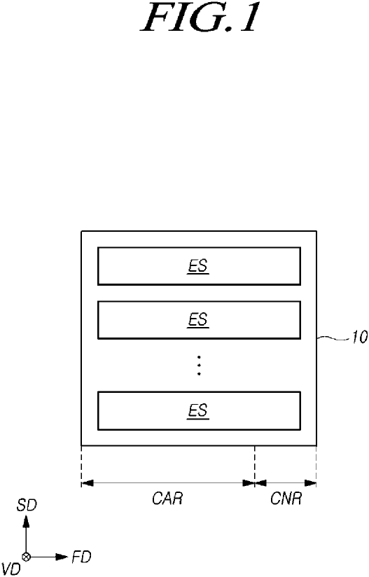

FIG. 1 is a schematic top view of a three-dimensional memory device in accordance with an embodiment of the present disclosure.

Referring to FIG. 1, a substrate 10 having a cell region CAR and a coupling region CNR may be provided.

The coupling region CNR may be adjacent to the cell region CAR in a first direction FD. The first direction FD may be an extending direction of word lines or an arrangement direction of bit lines. A second direction SD may be an extending direction of the bit lines or an arrangement direction of the word lines. The first direction FD and the second direction SD may be parallel to the top surface of the substrate 10 and may intersect with each other. A vertical direction VD indicates a direction vertically protruding from the top surface of the substrate 10.

A plurality of electrode structures ES may be disposed on the cell region CAR and the coupling region CNR of the substrate 10. The electrode structures ES may extend from the cell region CAR to the coupling region CNR in the first direction FD and may be arranged in the second direction SD.

As will be described later, each electrode structure ES may include a plurality of electrode layers, which are stacked in the vertical direction VD. The plurality of electrode layers may include a plurality of word lines. A plurality of memory cells that are three-dimensionally arranged may be disposed in the cell region CAR. Each of the plurality of memory cells may be coupled to a corresponding word line.

The pad portion of each electrode layer may be configured in the coupling region CNR. The pad portion is a portion of each electrode layer that is not covered by another electrode layer disposed over the electrode layer in the vertical direction VD, and a contact may be coupled to the pad portion. The electrode layer may be coupled to a row decoder through the contact, which is coupled to the pad portion, and may be provided with an electrical signal from the row decoder.

In order to configure pad portions, a plurality of etching processes may be used, including an etching process referred to as a Z-slim etching process. The Z-slim etching process etches a plurality of layers at once in the vertical direction VD in order to simultaneously form the pad portions of upper electrode layers and the pad portions of lower electrode layers. When the Z-slim etching process is used, it is possible to advantageously reduce the number of process steps required to configure the pad portions of the electrode layers.

In the Z-slim etching process, etching cannot be controlled by specifying a target layer because a plurality of dielectric layers and a plurality of sacrificial layers are etched together or in the same process step. Therefore, process conditions such as an etch energy and an etch time are adjusted according to the number and thickness of layers to be etched, and process margins are tightly managed in order to cause etching to be ended at a desired position. That is to say, process margins in z-slim etching are small in order to control the end of the etching process, which is a critical factor that determines an etch end position of the layers

When the shape and size of a region to be etched in the Z-slim etching process are changed to reduce the area of the coupling region CNR in order to further miniaturize memory devices, process conditions need to change. However, changing process conditions is not an easy task due to small process margins, which makes it difficult or impossible to use the Z-slim etching process.

When the use of the Z-slim etching process is not possible or not recommended, the number of process steps increases because the pad portions of the upper electrode layers and the pad portions of the lower electrode layers are formed using separate processes. This, may increase the time and cost consumed for the fabrication of a three-dimensional memory device.

Embodiments of the present disclosure suggest methods of improving process margins of Z-slim etching processes so that Z-slim etching processes can be used even when the shape or size of a region to be etched is changed or reduced.

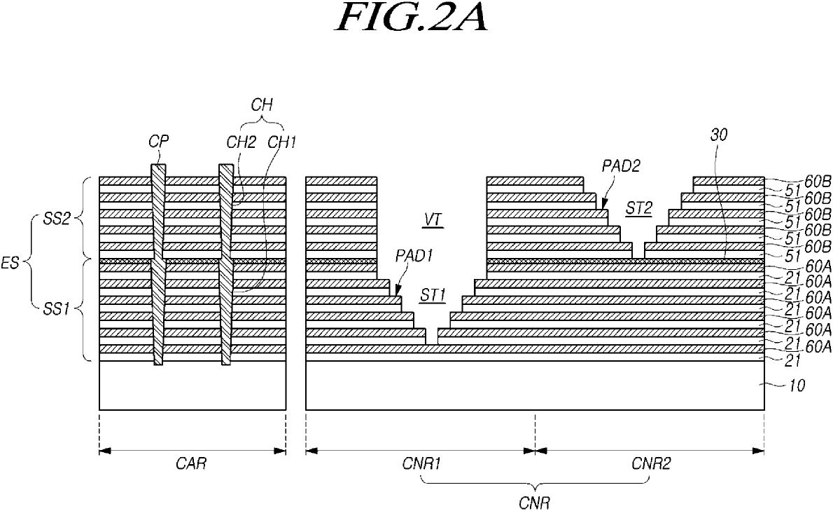

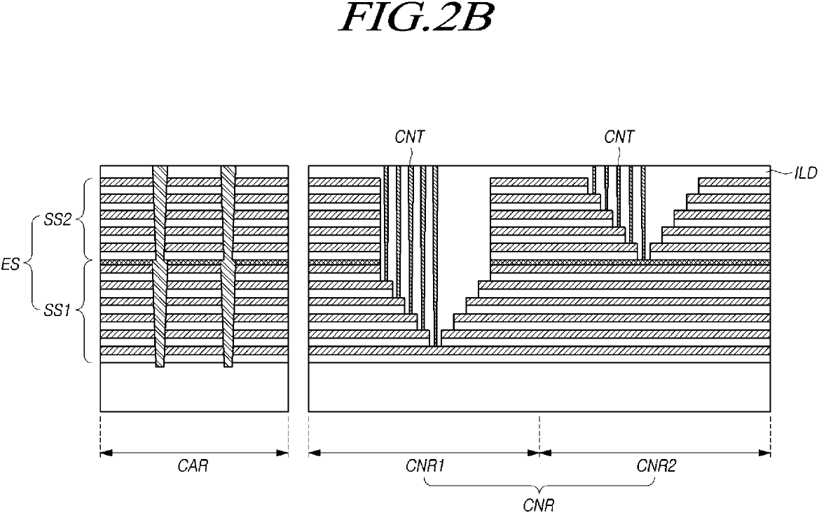

FIGS. 2A and 2B are cross-sectional views illustrating a three-dimensional memory device in accordance with an embodiment of the present disclosure.

Referring to FIG. 2A, a substrate 10 may be a silicon substrate, a germanium substrate or a silicon-germanium substrate. The substrate 10 may have a first conductivity type. For example, the substrate 10 may be a p-type.

An electrode structure ES may be configured on the substrate 10 in a cell region CAR and a coupling region CNR. The coupling region CNR may include a first region CNR1 and a second region CNR2.

The electrode structure ES may include a lower structure SS1 and an upper structure SS2 that is stacked on the lower structure SS1.

The lower structure SS1 may include a plurality of first dielectric layers 21 and a plurality of first electrode layers 60A, which are alternately stacked, and an etch stop layer 30. The etch stop layer 30 may be configured at the uppermost part of the lower structure SS1. The upper structure SS2 may include a plurality of second dielectric layers 51 and a plurality of second electrode layers 60B, which are alternately stacked.

The first and second electrode layers 60A and 60B may include at least one selected from among a doped semiconductor (e.g., doped silicon), a metal (e.g., tungsten, copper or aluminum), a conductive metal nitride (e.g., titanium nitride or tantalum nitride) and a transition metal (e.g., titanium or tantalum). The first and second dielectric layers 21 and 51 may include silicon oxide.

The etch stop layer 30 may include a conductive material. For example, the etch stop layer 30 may include at least one of polysilicon, tungsten and TiN.

The second dielectric layer 51 may be configured as the next immediate layer disposed on the etch stop layer 30. The lowermost second dielectric layer 51 of the upper structure SS2 may insulate the etch stop layer 30 from the lowermost second electrode layer 60B of the upper structure SS2.

The first electrode layer 60A may be configured as the next immediate layer under the etch stop layer 30. The etch stop layer 30 may directly contact the uppermost first electrode layer 60A of the lower structure SS1, and may be electrically coupled to the uppermost first electrode layer 60A of the lower structure SS1.

The first and second electrode layers 60A and 60B may configure row lines.

For example, from among the second electrode layers 60B, at least one second electrode layer 60B from the uppermost second electrode layer 60B may configure a drain select line. From among the first electrode layers 60A, at least one first electrode layer 60A from the lowermost first electrode layer 60A may configure a source select line.

Among the electrode layers 60A and 60B between the source select line and the drain select line, the uppermost first electrode layer 60A of the lower structure SS1 may configure a dummy word line, and the remaining electrode layers 60A and 60B, other than the uppermost first electrode layer 60A of the lower structure SS1, may configure word lines. Memory cells that are coupled to the word lines are used for data storage. Memory cells that are coupled to the dummy word line are not used for data storage.

The uppermost first electrode layer 60A of the lower structure SS1 and the etch stop layer 30 electrically connected thereto may constitute one word line. The word line constituted with the uppermost first electrode layer 60A of the lower structure SS1 and the etch stop layer 30 is effectively thicker than the word line constituted with other electrode layers. Accordingly, memory cells that are coupled to the uppermost first electrode layer 60A of the lower structure SS1 may have different characteristics from memory cells that are coupled to the other electrode layers 60A and 60B. By configuring the uppermost first electrode layer 60A of the lower structure SS1 as a dummy word line to prevent the degradation of reliability due to differences in the characteristics of the memory cells, the memory cells that are coupled to the uppermost first electrode layer 60A of the lower structure SS1 may not be used for data storage.

A plurality of channel holes CH that pass through the electrode structure ES may be formed in the cell region CAR. Each channel hole CH may include a lower channel hole CH1, which extends to the substrate 10 by passing through the lower structure SS1, and an upper channel hole CH2, which communicates with the lower channel hole CH1 by passing through the upper structure SS2.

Referring to FIG. 2A, the cross-sectional diameter of the lower channel hole CH1 may gradually decrease as the lower channel hole CH1 approaches the substrate 10. The cross-sectional diameter of the upper channel hole CH2 may gradually decrease as the upper channel hole CH2 approaches the substrate 10. Therefore, the cross-sectional diameter of the channel hole CH may have a nonuniform change in the vertical direction VD at the interface between the upper structure SS2 and the lower structure SS1. For example, at the interface between the upper structure SS2 and the lower structure SS1, the diameter of the channel hole CH may increase from the upper structure SS2 to the lower structure SS1.

A plurality of cell plugs CP may be configured in the plurality of channel holes CH. Although not illustrated in detail, each cell plug CP may include a channel layer and a gate dielectric layer. The channel layer may include polysilicon or monocrystalline silicon, and may include, in some regions thereof, a P-type impurity such as boron (B). The gate dielectric layer may have a shape that surrounds the outer wall of the channel layer. The gate dielectric layer may include a tunnel dielectric layer, a charge storage layer and a blocking layer, which are sequentially stacked from the outer wall of the channel layer. In some embodiments, the gate dielectric layer may have an ONO (oxide-nitride-oxide) stack structure in which an oxide layer, a nitride layer and an oxide layer are sequentially stacked.

A vertical trench VT, which passes through the upper structure SS2, is configured in the first region CNR1 of the coupling region CNR, and a first stairway-shaped trench ST1, which communicates with the vertical trench VT, may be configured in the lower structure SS1 under the vertical trench VT in the first region CNR1.

Each of the first electrode layers 60A of the lower structure SS1, when positioned as an underlying layer, may have a pad portion PAD1 that is not covered or vertically overlapped by electrode layers positioned over the underlying layer. The pad portions PAD1 of the first electrode layers 60A of the lower structure SS1 are disposed in the shape of a stairway, and a stairway structure may be formed on each sidewall of the first stairway-shaped trench ST1.

A second stairway-shaped trench ST2 may be configured in the upper structure SS2 in the second region CNR2 of the coupling region CNR.

Each of the second electrode layers 60B of the upper structure SS2, when positioned as an underlying layer, may have a pad portion PAD2 that is not covered vertically overlapped by the next electrode layer positioned above the underlying layer. The pad portions PAD2 of the second electrode layers 60B of the upper structure SS2 are disposed in the shape of a stairway, and a stairway structure may be formed on each sidewall of the second stairway-shaped trench ST2.

Referring to FIGS. 2A and 2B, an interlayer dielectric layer ILD that fills the first and second stairway-shaped trenches ST1 and ST2 and the vertical trench VT may be configured on the electrode structure ES.

Contacts CNT may be configured on the pad portions PAD1 and PAD2, respectively. Each contact CNT may be coupled to a corresponding pad portion by vertically passing through the interlayer dielectric layer ILD.

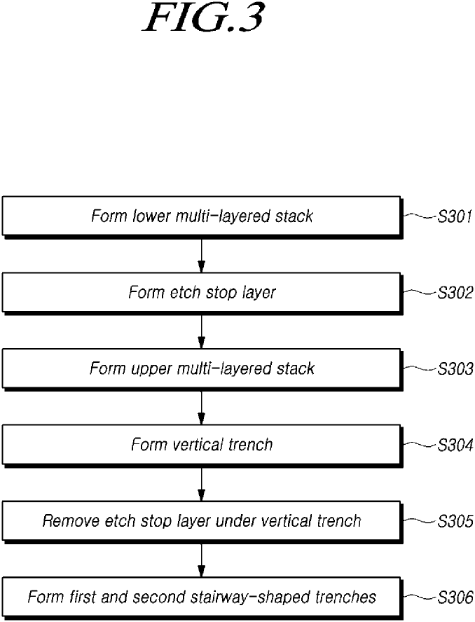

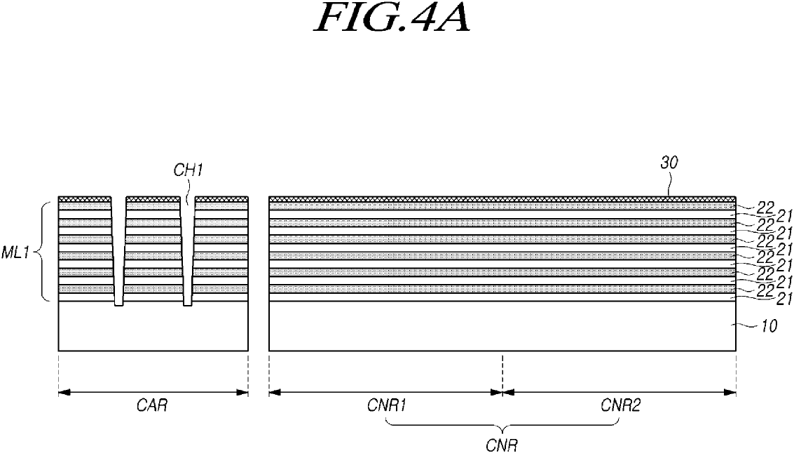

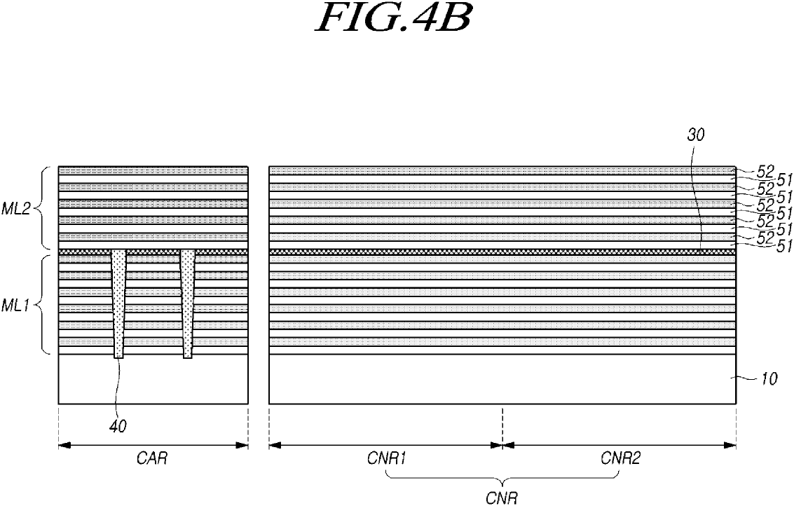

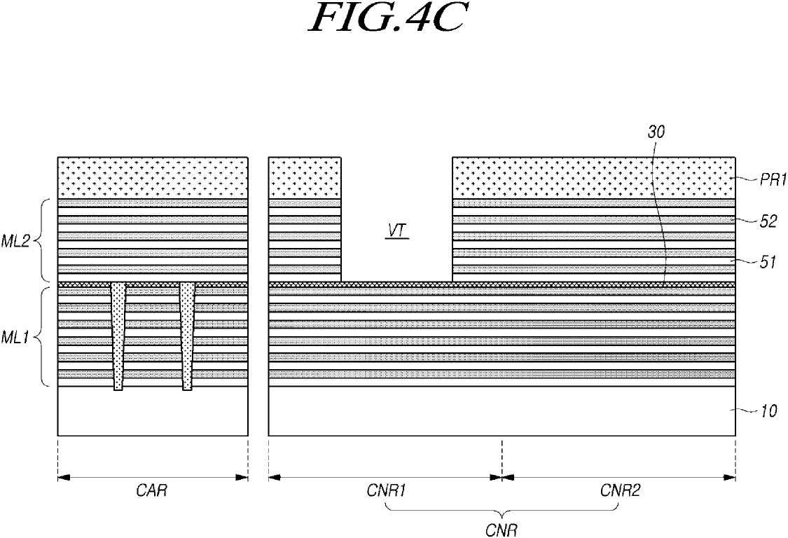

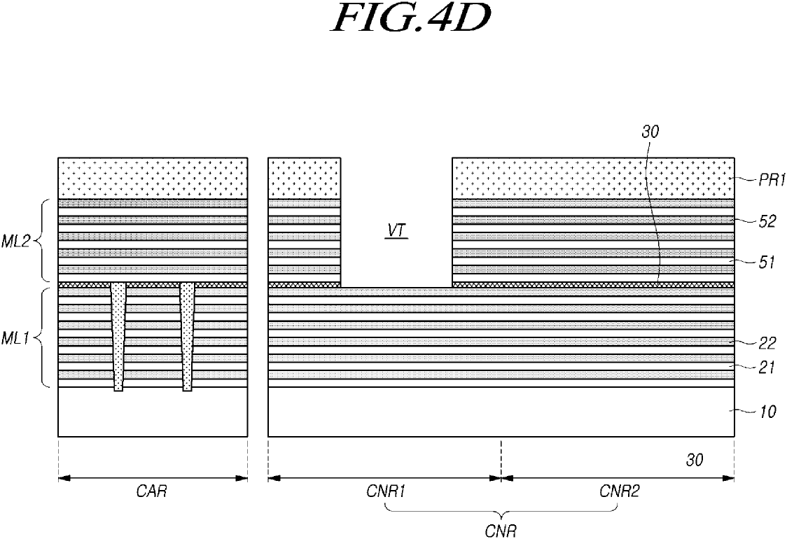

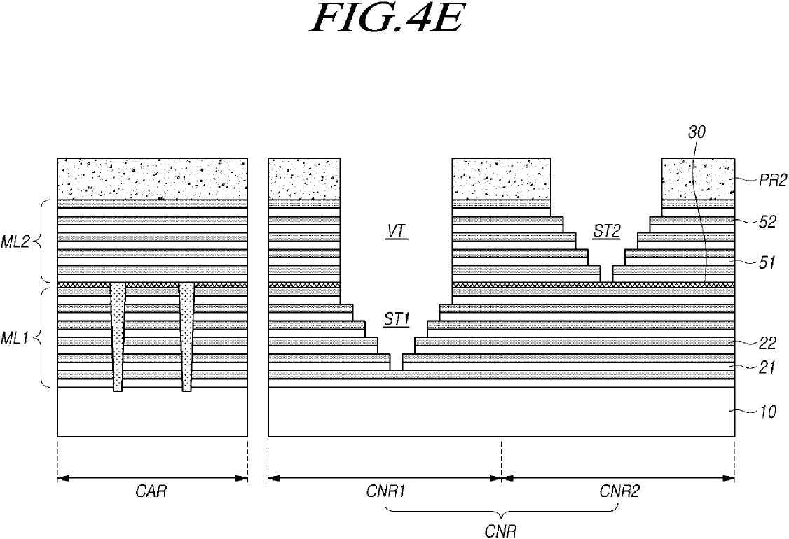

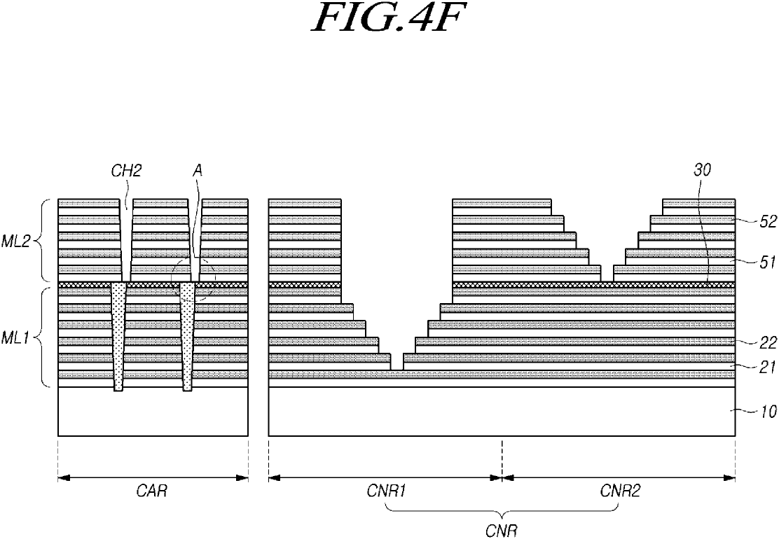

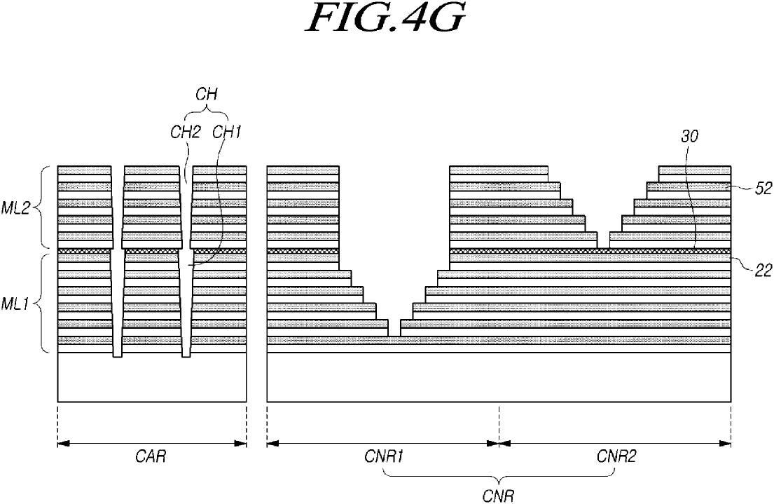

FIG. 3 is a flowchart illustrating a method for manufacturing a three-dimensional memory device in accordance with an embodiment of the present disclosure, and FIGS. 4A to 4G are cross-sectional views illustrating, by manufacturing steps, a three-dimensional memory device in accordance with an embodiment of the present disclosure.

Referring to FIGS. 3 and 4A to 4G, a method for manufacturing a three-dimensional memory device in accordance with an embodiment of the present disclosure may include forming a lower multi-layered stack ML1 by alternately stacking a plurality of first dielectric layers 21 and a plurality of first sacrificial layers 22 on a substrate 10 (S301); forming an etch stop layer 30 on the lower multi-layered stack ML1 (S302); forming an upper multi-layered stack ML2 by alternately stacking a plurality of second dielectric layers 51 and a plurality of second sacrificial layers 52 on the etch stop layer 30 (S303); forming a vertical trench VT by etching the upper multi-layered stack ML2 using the etch stop layer 30 as an etch end target (S304); removing the etch stop layer 30 under the vertical trench VT (S305); and forming a first stairway-shaped trench ST1 in the lower multi-layered stack ML1 under the vertical trench VT and forming a second stairway-shaped trench ST2 in the upper multi-layered stack ML2 (S306).

A method for manufacturing a three-dimensional memory device in accordance with an embodiment of the present disclosure will be described below in more detail.

Referring to FIG. 4A, the lower multi-layered stack ML1 may be formed by alternately stacking the plurality of first dielectric layers 21 and the plurality of first sacrificial layers 22 on the substrate 10.

The plurality of first dielectric layers 21 and the plurality of first sacrificial layers 22 may be formed of dielectric materials that have different etch selectivities. For example, the plurality of first dielectric layers 21 may be formed of silicon oxide, and the plurality of first sacrificial layers 22 may be formed of silicon nitride. The uppermost layer of the lower multi-layered stack ML1 may be the first sacrificial layer 22, as an example.

The etch stop layer 30 may be formed on the lower multi-layered stack ML1. The etch stop layer 30 may have a thickness that is less than the thicknesses of plurality of first sacrificial layers 22 and the plurality of second sacrificial layers 52, to be described later with reference to FIG. 4B.

The etch stop layer 30 may serve as an etch end target in a Z-slim etching process in which a vertical trench VT is formed by etching the upper multi-layered stack ML2, to be described later with reference to FIG. 4C. The etch stop layer 30 may be formed of a material that has an etch selectivity different from the plurality of second dielectric layers 51 and the plurality of second sacrificial layers 52 of the upper multi-layered stack ML2. For example, the plurality of second dielectric layers 51 may be formed of silicon oxide, the plurality of second sacrificial layers 52 may be formed of silicon nitride, and the etch stop layer 30 may be formed of at least one of polysilicon, tungsten and TiN.

A plurality of lower channel holes CH1, which extend to the substrate 10 by passing vertically through the etch stop layer 30 and the lower multi-layered stack ML1, may be formed in a cell region CAR.

The forming of the lower channel holes CH1 may include forming, on the etch stop layer 30, a mask pattern having openings that define regions where the lower channel holes CH1 are to be formed and etching the etch stop layer 30 and the lower multi-layered stack ML1 using the mask pattern as an etch mask. The remaining mask pattern may be removed.

Referring to FIG. 4B, sacrificial dielectric patterns 40 may be formed in the plurality of lower channel holes CH1.

The forming of the sacrificial dielectric patterns 40 may include forming, on the lower multi-layered stack ML1, a sacrificial dielectric layer that fills the lower channel holes CH1 and then planarizing the sacrificial dielectric layer until the top surface of the etch stop layer 30 is exposed.

The upper multi-layered stack ML2 may be formed by alternately stacking the plurality of second dielectric layers 51 and the plurality of second sacrificial layers 52 on the etch stop layer 30 and the sacrificial dielectric patterns 40.

The forming of the plurality of second dielectric layers 51 and the plurality of second sacrificial layers 52 may be substantially the same as described above in the process of forming the plurality of first dielectric layers 21 and the plurality of first sacrificial layers 22 of the lower multi-layered stack ML1.

Referring to FIG. 4C, the vertical trench VT, which exposes the etch stop layer 30 by passing through the upper multi-layered stack ML2, may be formed.

The forming of the vertical trench VT may include forming, on the upper multi-layered stack ML2, a mask pattern PR1 that exposes a portion of a first region CNR1 of a coupling region CNR and etching the upper multi-layered stack ML2 exposed by the mask pattern PR1 by a Z-slim etching process using the etch stop layer 30 as an etch end target.

The etch stop layer 30 has an etch selectivity different from the etch selectivity of the plurality of second dielectric layers 51 and the plurality of second sacrificial layers 52, so the Z-slim etching process is controlled by using the differences in etch selectivity such that etching is stopped at the etch stop layer 30. Accordingly, it is not necessary to precisely control process conditions such as an etch energy and an etch time in order to cause etching to be end at a desired position and thus process margins may be improved.

Referring to FIG. 4D, the etch stop layer 30 which is exposed through the vertical trench VT may be removed to expose the lower multi-layered stack ML1 at the bottom of the vertical trench VT. The remaining mask pattern PR1 may be removed.

Referring to FIG. 4E, the first stairway-shaped trench ST1 may be formed in the lower multi-layered stack ML1 under the vertical trench VT of a first region CNR1, and the second stairway-shaped trench ST2 may be formed in the upper multi-layered stack ML2 of a second region CNR2.

The forming of the first and second stairway-shaped trenches ST1 and ST2 may include forming, on the upper multi-layered stack ML2, a mask pattern PR2 having openings that expose a portion of the lower multi-layered stack ML1 exposed by the vertical trench VT and a portion of the upper multi-layered stack ML2 of a second region CNR2 of the coupling region CNR, performing an etching process of etching the portions of the lower multi-layered stack ML1 and the upper multi-layered stack ML2 using the mask pattern PR2 as an etch mask, performing a slimming process of reducing the mask pattern PR2, and alternately repeating the etching process and the slimming process.

The etching process may include etching the first and second sacrificial layers 22 and 52 and the first and second dielectric layers 21 and 51 that are exposed by the mask pattern PR2. A vertical depth etched in one etching process may correspond to the distance between the top surfaces of vertically adjacent sacrificial layers 22 or vertically adjacent sacrificial layers 52.

The slimming process includes etching the mask pattern PR2 to reduce the width and thickness of the mask pattern PR2. Using the slimming process, the sidewalls of the mask pattern PR2 may be modified in a horizontal direction to widen the areas of the openings of the mask pattern PR2 for subsequent etching cycles.

The mask pattern PR2 may be formed of a photoresist, and the mask pattern PR2 remaining after forming the first and second stairway-shaped trenches ST1 and ST2 may be removed by a stripping process.

Although not illustrated for the sake of simplicity in illustration, an interlayer dielectric layer, which fills the first and second stairway-shaped trenches ST1 and ST2 and the vertical trench VT, may be formed.

Referring to FIG. 4F, upper channel holes CH2 may be formed to pass vertically through the upper multi-layered stack ML2 in the cell region CAR and to expose the sacrificial dielectric patterns 40.

The forming of the upper channel holes CH2 may include forming, on the upper multi-layered stack ML2, a mask pattern having openings that define regions where the upper channel holes CH2 are to be formed and etching the upper multi-layered stack ML2 using the mask pattern as an etch mask. The remaining mask pattern may be removed.

Each of the upper channel holes CH2 may be formed to vertically overlap with a corresponding sacrificial dielectric pattern 40. In FIG. 4F, part A illustrates a misalignment between the sacrificial dielectric patterns 40 and the upper channel holes CH2 when the upper channel holes CH2 are formed, and as a result, the etch stop layer 30 may prevent the lower multi-layered stack ML1 from being etched.

Referring to FIG. 4G, the sacrificial dielectric patterns 40 that are exposed through the upper channel holes CH2 may be removed so that each lower channel hole CH1 and each corresponding upper channel hole CH2 may communicate with each other to configure one channel hole CH.

Referring back to FIG. 2A, the cell plug CP may be formed in each channel hole CH, and the first and second sacrificial layers 22 and 52 may be replaced with the first and second electrode layers 60A and 60B, respectively.

The replacement of the first and second sacrificial layers 22 and 52 with the first and second electrode layers 60A and 60B may include removing the first and second sacrificial layers 22 and 52 and then filling spaces created by the removal of the first and second sacrificial layers 22 and 52 with an electrode material.

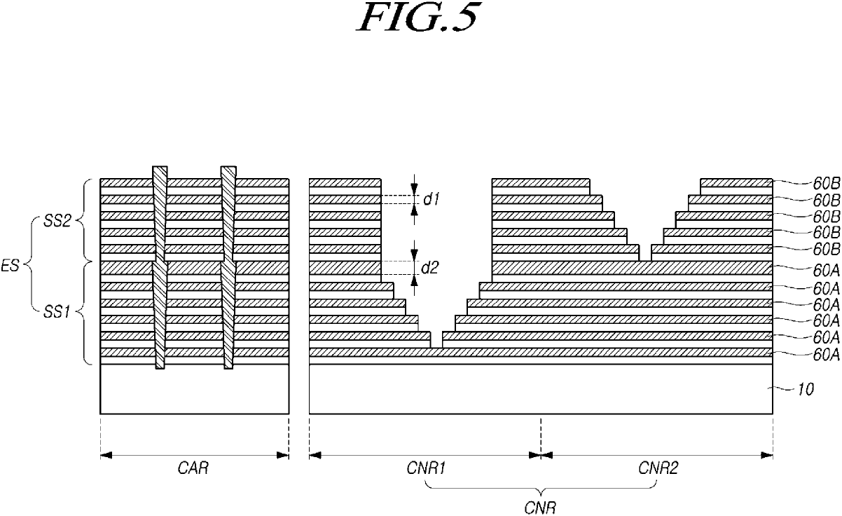

FIGS. 5 to 7 are cross-sectional views illustrating three-dimensional memory devices in accordance with various embodiments of the present disclosure. Hereinafter, the description with reference to FIGS. 5 to 7 may omit repeating of descriptions of the same components as those described above with reference to FIGS. 2A to 4G and may only describe differences in components or structures.

Referring to FIG. 5, a first electrode layer 60A may be configured at the uppermost part of the lower structure SS1. Unlike the embodiment of FIGS. 2A and 2B, the lower structure SS1 may not include an etch stop layer 30 as shown in FIG. 5.

The uppermost first electrode layer 60A of the lower structure SS1 may have a thickness that is different from the thickness of the other electrode layers.

Unlike the embodiment described above with reference to FIGS. 4A to 4G, after removing the first and second sacrificial layers 22 and 52, and before filling an electrode material into spaces created by the removal of the first and second sacrificial layers 22 and 52, a process of removing the etch stop layer 30 may be further performed. As a result, electrode material may fill in spaces created by the removal of the first and second sacrificial layers 22 and 52 and the etch stop layer 30.

The uppermost first electrode layer 60A of the lower structure SS1 may be configured by the electrode material that fills in a space created by the removal of the uppermost first sacrificial layer 22 of the lower multi-layered stack ML1 and the etch stop layer 30. Consequently, the uppermost first electrode layer 60A of the lower structure SS1 may have a thickness corresponding to a sum of the thickness of the uppermost first sacrificial layer 22 of the lower multi-layered stack ML1 and a thickness of the etch stop layer 30. The uppermost first electrode layer 60A of the lower structure SS1 may be thicker than the other electrode layers. For example, when the thickness of the other electrode layers except the uppermost first electrode layer 60A of the lower structure SS1 is d1, the uppermost first electrode layer 60A of the lower structure SS1 may have a thickness d2, which is larger than d1.

The uppermost first electrode layer 60A of the lower structure SS1 may configure a dummy word line. Memory cells that are coupled to the uppermost first electrode layer 60A of the lower structure SS1 may have characteristics that are different from memory cells that are coupled to the other electrode layers because the uppermost first electrode layer 60A of the lower structure SS1 has a thickness that is different from the thickness of other electrode layers. In order to prevent any degradation of reliability due to differences in the characteristics of the memory cells, the uppermost first electrode layer 60A of the lower structure SS1 may be configured as a dummy word line.

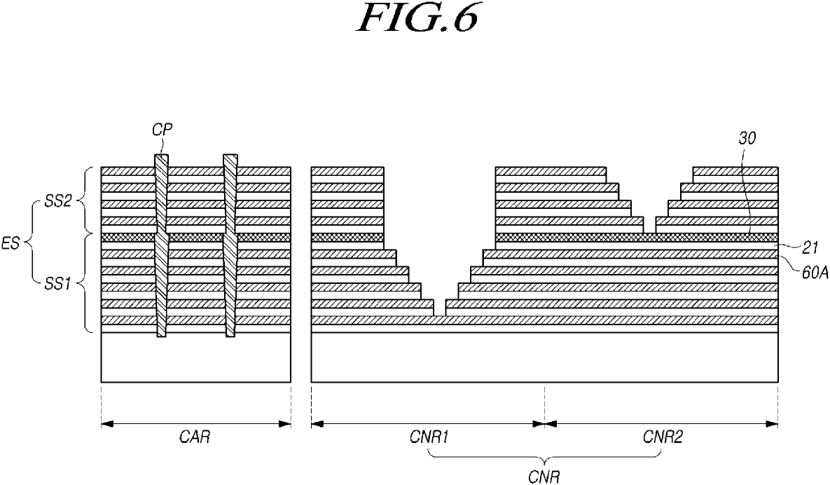

Referring to FIG. 6, a first dielectric layer 21 may be configured immediately under the etch stop layer 30. The uppermost first dielectric layer 21 of the lower structure SS1 may insulate the etch stop layer 30 from the uppermost first electrode layer 60A of the lower structure SS1.

Unlike the embodiment described above with reference to FIGS. 4A to 4G, the uppermost layer of the lower multi-layered stack ML1 may be the first dielectric layer 21, and the etch stop layer 30 may be insulated from the uppermost first electrode layer 60A of the lower structure SS1 by the first dielectric layer 21.

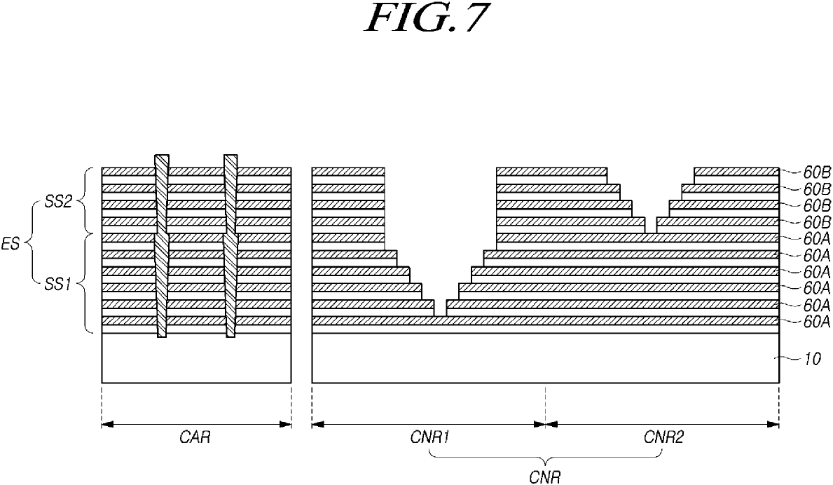

Referring to FIG. 7, a first electrode layer 60A may be configured at the uppermost part of the lower structure SS1. Unlike the embodiment of FIGS. 2A and 2B, the lower structure SS1 may not include an etch stop layer 30 as shown in FIG. 7.

Unlike the embodiment described above with reference to FIGS. 4A to 4G, the uppermost layer of the lower multi-layered stack ML1 may be the first dielectric layer 21. Also, unlike the embodiment described above with reference to FIGS. 4A to 4G, after removing the first and second sacrificial layers 22 and 52, and before filling an electrode material into spaces created by the removal of the first and second sacrificial layers 22 and 52, a process of removing the etch stop layer 30 may be further performed. As a result, the electrode material may fill in spaces created by the removal of the first and second sacrificial layers 22 and 52 and the etch stop layer 30.

The uppermost first electrode layer 60A of the lower structure SS1 may be configured by the electrode material used to fill in a space created by the removal of the etch stop layer 30. The uppermost first electrode layer 60A of the lower structure SS1 may have the same thickness as the etch stop layer 30.

When the etch stop layer 30 has the same thickness as the first and second sacrificial layers 22 and 52, the uppermost first electrode layer 60A of the lower structure SS1 may have the same thickness as the other electrode layers. Thus, the uppermost first electrode layer 60A of the lower structure SS1 may configure a word line.

Since the uppermost first electrode layer 60A of the lower structure SS1 has the same thickness as the other electrode layers, the characteristics of memory cells that are coupled to the uppermost first electrode layer 60A of the lower structure SS1 may not be different from the characteristics of memory cells which are coupled to the other electrode layers. Because reliability is not degraded in the memory cells that are coupled to the uppermost first electrode layer 60A of the lower structure SS1 and are used to store data, the uppermost first electrode layer 60A of the lower structure SS1 may be configured as a word line to increase memory capacity.

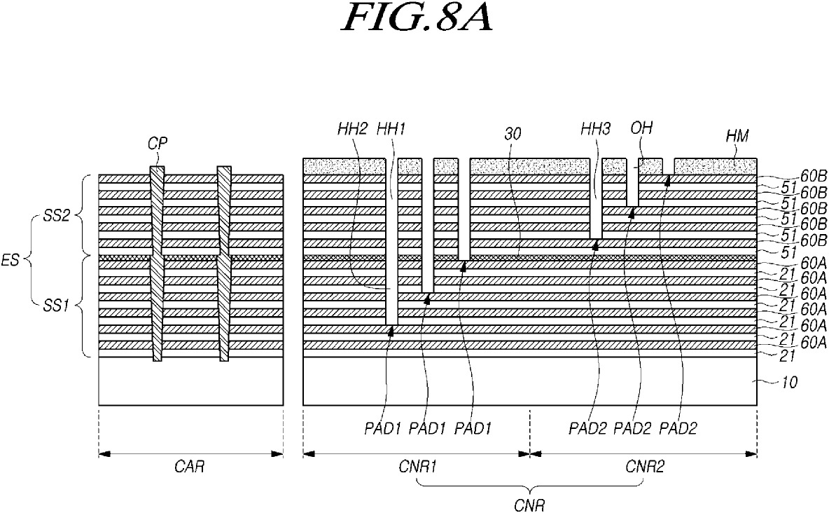

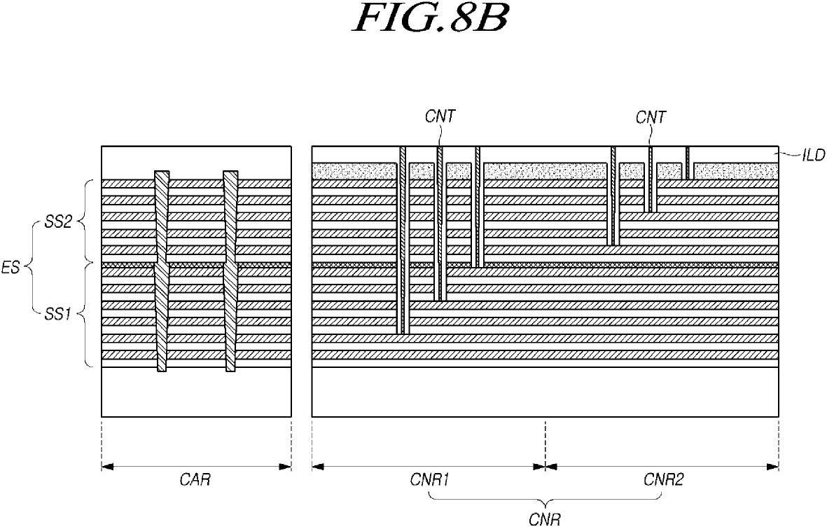

Hereinafter, other embodiments of the present disclosure will be described with reference to FIGS. 8A to 10G. In the following description to be made with reference to FIGS. 8A to 10G, descriptions of the same components as those described above with reference to FIGS. 2A to 4G will not be repeated.

FIGS. 8A and 8B are cross-sectional views illustrating a three-dimensional memory device in accordance with an embodiment of the present disclosure.

Referring to FIG. 8A, an electrode structure ES configured as a lower structure SS1 and an upper structure SS2 are sequentially stacked on a substrate 10 in a cell region CAR and a coupling region CNR.

The lower structure SS1 may include a plurality of first dielectric layers 21 and a plurality of first electrode layers 60A, which are alternately stacked. An etch stop layer 30 may be provided at the uppermost part of the lower structure SS1. The upper structure SS2 may include a plurality of second dielectric layers 51 and a plurality of second electrode layers 60B, which are alternately stacked.

In a first region CNR1 of the coupling region CNR, a plurality of first vertical holes HH1, which pass vertically through the upper structure SS2, may be formed, and a plurality of second vertical holes HH2, which extend downward vertically from the plurality of first vertical holes HH1, may be formed in the lower structure SS1. The bottom surfaces of the plurality of second vertical holes HH2 may be positioned at different vertical heights relative to the top surface of the substrate 10.

The first vertical hole HH1 and the second vertical hole HH2, which are disposed on the same a vertical line, may communicate with each other to configure one hole HH1 and HH2. A plurality of holes HH1 and HH2 may be configured in the first region CNR1 of the coupling region CNR. Each of the plurality of holes HH1 and HH2 may expose a pad portion PAD1 of a corresponding first electrode layer 60A.

A plurality of third vertical holes HH3 may be formed in the upper structure SS2 in a second region CNR2 of the coupling region CNR. The bottom surfaces of the plurality of third vertical holes HH3 may be positioned at different vertical heights relative to the top surface of the substrate 10. Each of the plurality of third vertical holes HH3 may expose a pad portion PAD2 of a corresponding second electrode layer 60B. For the sake of simplicity in illustration, only some of the first to third vertical holes HH1 to HH3 are illustrated in FIG. 8A.

A hard mask pattern HM may be additionally provided on the electrode structure ES in the coupling region CNR. The hard mask pattern HM serves as an etch mask in etching processes for forming the first to third vertical holes HH1 to HH3. The hard mask pattern HM includes a plurality of opening holes OH that expose the first to third vertical holes HH1 to HH3.

Referring to FIGS. 8A and 8B, an interlayer dielectric layer ILD, which fills the first to third vertical holes HH1 to HH3, may also be configured on the upper structure SS2.

Contacts CNT may be configured on the pad portions PAD1 and PAD2. Each contact CNT may be coupled to a corresponding pad portion by passing vertically through the interlayer dielectric layer ILD.

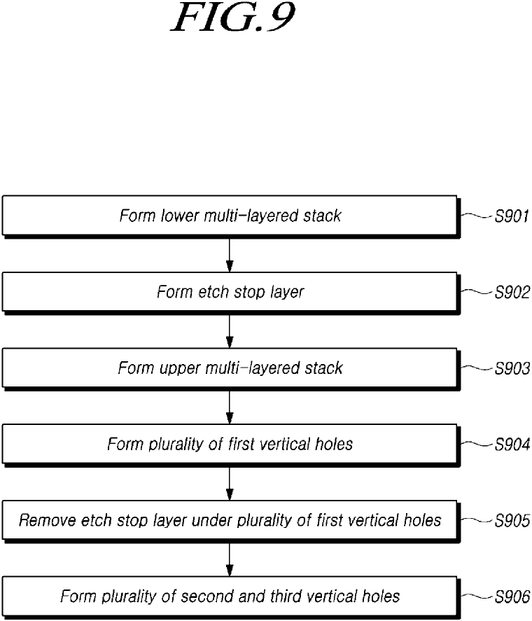

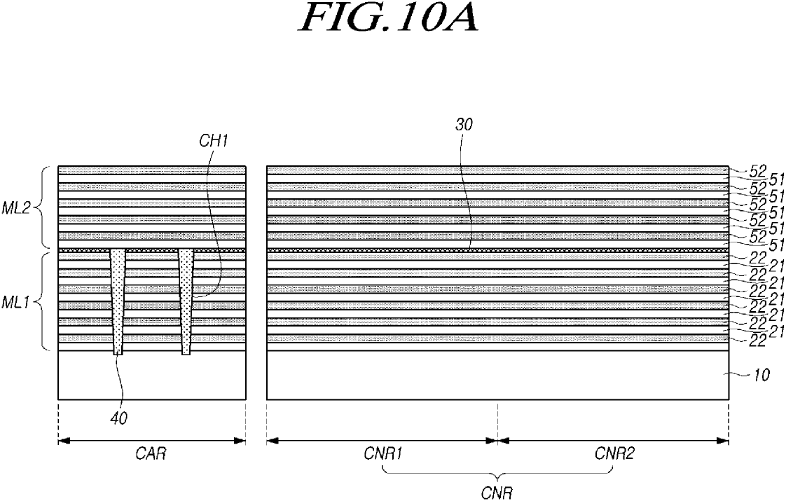

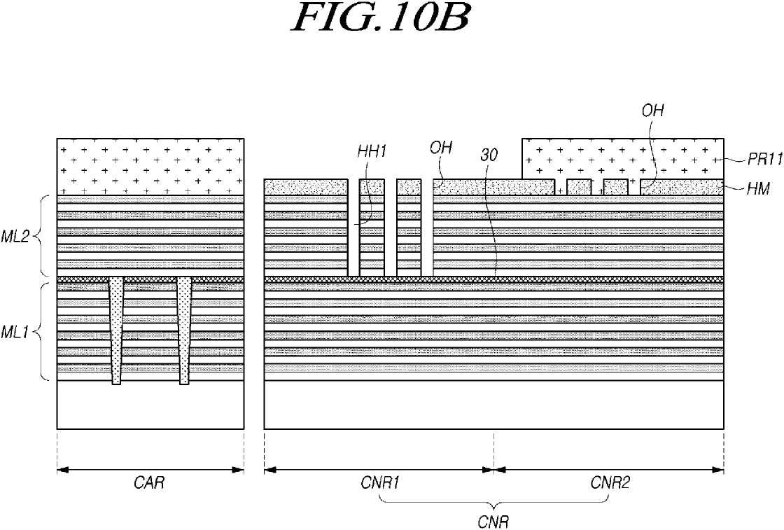

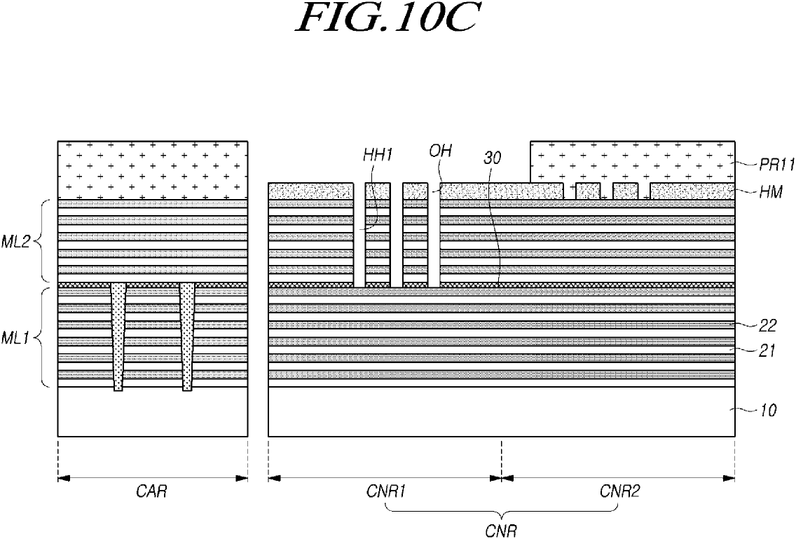

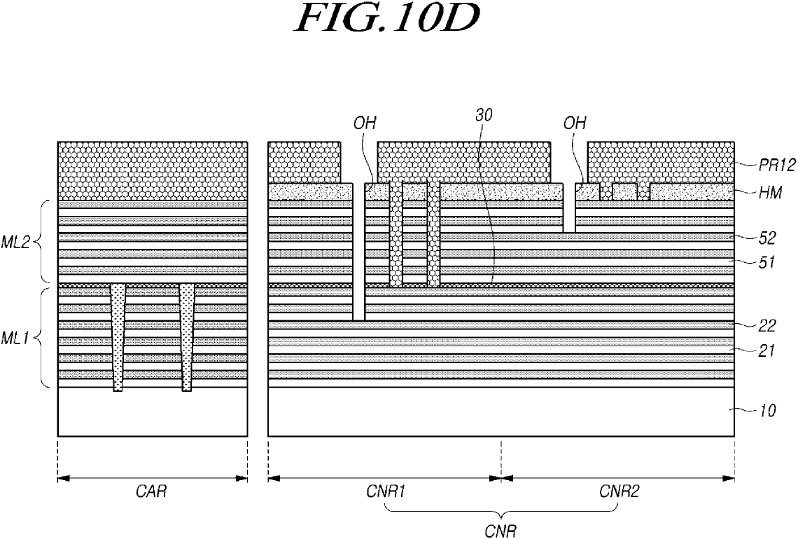

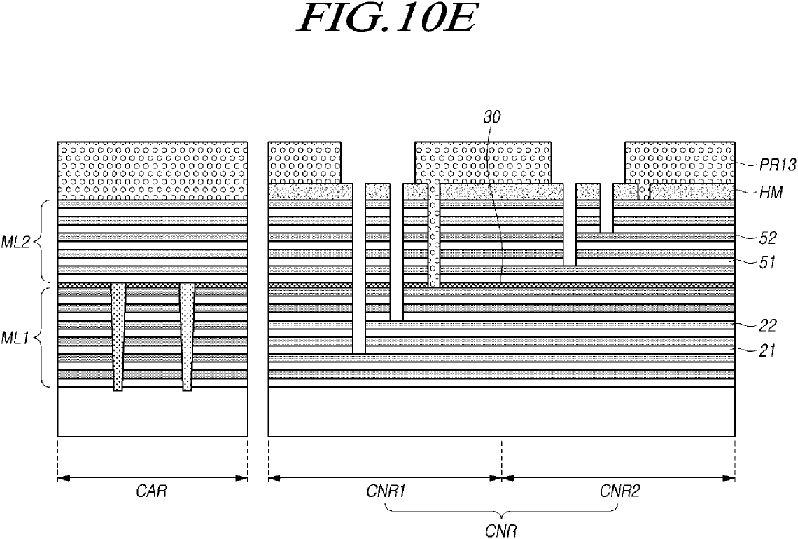

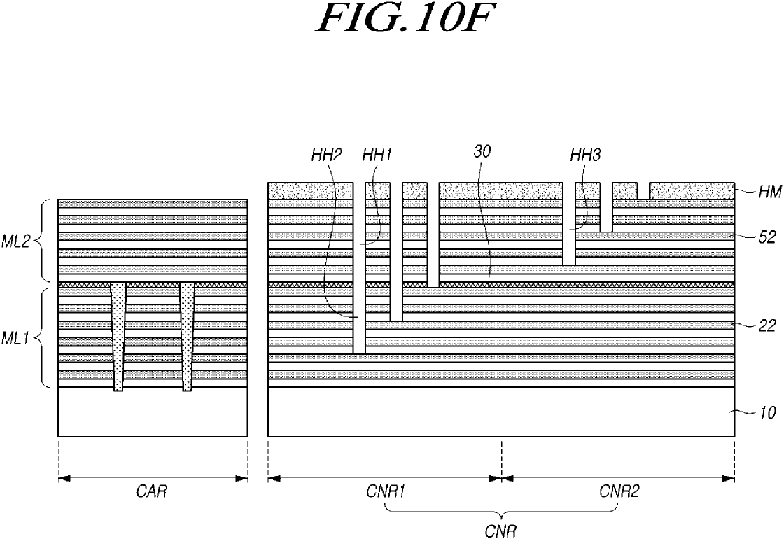

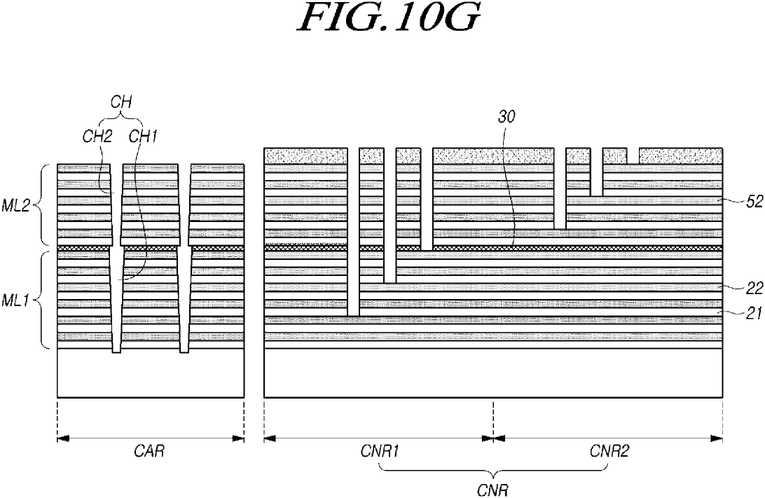

FIG. 9 is a flowchart illustrating a method for manufacturing a three-dimensional memory device in accordance with an embodiment of the present disclosure, and FIGS. 10A to 10G are cross-sectional views illustrating, by manufacturing steps, a three-dimensional memory device in accordance with an embodiment of the present disclosure.

Referring to FIGS. 9 and 10A to 10G, a method for manufacturing a three-dimensional memory device in accordance with an embodiment of the present disclosure may include forming a lower multi-layered stack ML1 by alternately stacking a plurality of first dielectric layers 21 and a plurality of first sacrificial layers 22 on a substrate 10 (S901); forming an etch stop layer 30 on the lower multi-layered stack ML1 (S902); forming an upper multi-layered stack ML2 by alternately stacking a plurality of second dielectric layers 51 and a plurality of second sacrificial layers 52 on the etch stop layer 30 (S903); forming a plurality of first vertical holes HH1 by etching the upper multi-layered stack ML2 using the etch stop layer 30 as an etch end target (S904); removing the etch stop layer 30 under the plurality of first vertical holes HH1 (S905); and forming, in the lower multi-layered stack ML1, a plurality of second vertical holes HH2 that extend downward from the plurality of first vertical holes HH1 and whose bottom surfaces are positioned at different heights from the top surface of the substrate 10 and forming, in the upper multi-layered stack ML2, a plurality of third vertical holes HH3 whose bottom surfaces are positioned at different heights from the top surface of the substrate 10 (S906).

The method for manufacturing a three-dimensional memory device in accordance with an embodiment of the present disclosure will be described below in more detail.

Referring back to FIG. 10A, in a cell region CAR and a coupling region CNR, the lower multi-layered stack ML1 may be formed by alternately stacking the plurality of first dielectric layers 21 and the plurality of first sacrificial layers 22 on the substrate 10, and the etch stop layer 30 may be formed on the lower multi-layered stack ML1.

A plurality of lower channel holes CH1, which extend to the substrate 10 by passing through the etch stop layer 30 and the lower multi-layered stack ML1, may be formed in the cell region CAR, and sacrificial dielectric patterns 40 may be formed in the plurality of lower channel holes CH1.

The upper multi-layered stack ML2 may be formed by alternately stacking the plurality of second dielectric layers 51 and the plurality of second sacrificial layers 52 on the etch stop layer 30 and the sacrificial dielectric patterns 40.

The forming of the lower multi-layered stack ML1, the forming of the etch stop layer 30, the forming of the lower channel holes CH1, the forming of the sacrificial dielectric patterns 40 and the forming of the upper multi-layered stack ML2 may be substantially the same as described above in the processes described above with reference to FIGS. 4A and 4B.

Referring to FIG. 10B, a plurality of first vertical holes HH1, which expose the etch stop layer 30 by passing through the upper multi-layered stack ML2, may be formed.

The forming of the plurality of first vertical holes HH1 may include forming a hard mask pattern HM, which has a plurality of opening holes OH, on the upper multi-layered stack ML2 in the coupling region CNR, forming a mask pattern PR11, which exposes a first region CNR1, on the upper multi-layered stack ML2 and the hard mask pattern HM, and etching the upper multi-layered stack ML2 exposed by the mask pattern PR11 and the hard mask pattern HM through a Z-slim etching process that uses the etch stop layer 30 as an etch end target.

Referring to FIG. 10C, the etch stop layer 30 that is exposed through the plurality of first vertical holes HH1 may be removed. As a result, the lower multi-layered stack ML1 is exposed by the plurality of first vertical holes HH1. The mask pattern PR11 may be removed.

Referring to FIG. 10D, a mask pattern PR12, which has openings exposing at least one of the opening holes OH of the first region CNR1 and at least one of the opening holes OH of a second region CNR2, may be formed on the upper multi-layered stack ML2 and the hard mask pattern HM.

The lower multi-layered stack ML1 and the upper multi-layered stack ML2 exposed by the mask pattern PR12 and the hard mask pattern HM may be partially etched. The mask pattern PR12 may be removed.

The etching process may include etching the first and second sacrificial layers 22 and 52 and the first and second dielectric layers 21 and 51, which are exposed by the mask pattern PR12 and the hard mask pattern HM. The etching thickness of the etching process may correspond to an integer multiplied by the distance between the top surfaces of vertically adjacent sacrificial layers 22, 52.

Referring to FIG. 10E, a mask pattern PR13, which exposes at least one of the opening holes OH of the first region CNR1 and at least one of the opening holes OH of the second region CNR2, may be formed on the upper multi-layered stack ML2 and the hard mask pattern HM.

The position and/or number of the opening holes OH exposed by the mask pattern PR13 may be different from the position and/or number of the opening holes OH exposed by the mask pattern PR12 described above with reference to FIG. 10D.

The lower multi-layered stack ML1 and the upper multi-layered stack ML2 exposed by the mask pattern PR13 and the hard mask pattern HM may be partially etched. The mask pattern PR13 may be removed.

The partial etching of the lower multi-layered stack ML1 and the upper multi-layered stack ML2 may be substantially the same as the process described above with reference to FIG. 10D.

By repeating an etching process a number of times using a plurality of mask patterns having different positions and/or numbers of exposed opening holes OH as etch masks, as illustrated in FIG. 10F, a plurality of second vertical holes HH2 are formed in the lower multi-layered stack ML1 under the first vertical holes HH1 in the first region CNR1, and a plurality of third vertical holes HH3 are formed in the upper multi-layered stack ML2 in the second region CNR2.

The first vertical hole HH1 and the second vertical hole HH2, which are disposed on the same vertical line, may communicate with each other to configure one hole HH1 and HH2. A plurality of holes HH1 and HH2 may be configured in the first region CNR1 of the coupling region CNR. The bottom surfaces of the plurality of holes HH1 and HH2 may be positioned at different heights from the top surface of the substrate 10. Each of the plurality of holes HH1 and HH2 may expose a corresponding first sacrificial layer 22.

The bottom surfaces of the plurality of third vertical holes HH3 may be positioned at different heights from the top surface of the substrate 10. Each of the plurality of third vertical holes HH3 may expose a corresponding second sacrificial layer 52. For the sake of simplicity in illustration, only some of the first to third vertical holes HH1 to HH3 are illustrated in the drawings.

Although not illustrated for the sake of simplicity in illustration, an interlayer dielectric layer, which fills the plurality of first to third vertical holes HH1 to HH3, may also be formed on the upper multi-layered stack ML2 and the hard mask pattern HM.

Referring to FIG. 10G, upper channel holes CH2, which respectively expose the corresponding sacrificial dielectric patterns 40 by passing through the upper multi-layered stack ML2, may be formed in the cell region CAR, and the sacrificial dielectric patterns 40, which are exposed through the upper channel holes CH2, may be removed. Thus, each lower channel hole CH1 and each upper channel hole CH2 may communicate with each other to configure one channel hole CH.

The forming of the upper channel holes CH2 and the removing of the sacrificial dielectric patterns 40 may be substantially the same as in the processes described above with reference to FIGS. 4F and 4G.

Referring back to FIG. 8A, cell plugs CP may be formed in the channel holes CH, and the first and second sacrificial layers 22 and 52 may be replaced with the first and second electrode layers 60A and 60B.

The forming of the cell plugs CP and the replacing of the first and second sacrificial layers 22 and 52 with the first and second electrode layers 60A and 60B may be substantially the same as in the processes described above with reference to FIG. 2A.

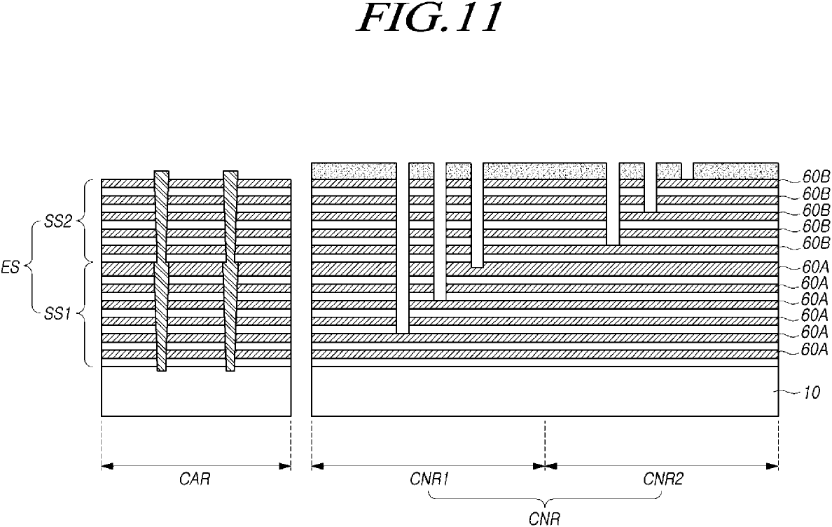

FIGS. 11 to 13 are cross-sectional views illustrating three-dimensional memory devices in accordance with various embodiments of the present disclosure. Hereinafter, descriptions of the same components as those described above with reference to FIGS. 8A to 10G will be omitted, and only differences may be described.

Referring to FIG. 11, a first electrode layer 60A may be configured at the uppermost part of the lower structure SS1. Unlike the embodiment of FIGS. 8A to 10G, the lower structure SS1 may not include an etch stop layer 30 as shown in FIG. 11. The uppermost first electrode layer 60A of the lower structure SS1 may have a thickness that is different from the thickness of other electrode layers.

Unlike the embodiment described above with reference to FIGS. 10A to 10G, after removing the first and second sacrificial layers 22 and 52 and before filling an electrode material into spaces created by the removal of the first and second sacrificial layers 22 and 52, a process of removing the etch stop layer 30 may be further performed. As a result, the electrode material may fill in spaces created by the removal of the first and second sacrificial layers 22 and 52 and the etch stop layer 30.

The uppermost first electrode layer 60A of the lower structure SS1 may be configured by the electrode material that fills in a space created by the removal of the uppermost first sacrificial layer 22 of the lower multi-layered stack ML1 and the etch stop layer 30. Thus, the uppermost first electrode layer 60A of the lower structure SS1 may have a thickness corresponding to a sum of the thickness of the uppermost first sacrificial layer 22 of the lower multi-layered stack ML1 and a thickness of the etch stop layer 30. The uppermost first electrode layer 60A of the lower structure SS1 may be thicker than the other electrode layers.

The uppermost first electrode layer 60A of the lower structure SS1 may configure a dummy word line. Because the uppermost first electrode layer 60A of the lower structure SS1 has a thickness that is different from the thickness of the other electrode layers, memory cells which are coupled to the uppermost first electrode layer 60A of the lower structure SS1 may have characteristics different memory cells that are coupled to the other electrode layers. In order to prevent any degradation of reliability due to differences in the characteristics of the memory cells, the uppermost first electrode layer 60A of the lower structure SS1 may be configured as a dummy word line.

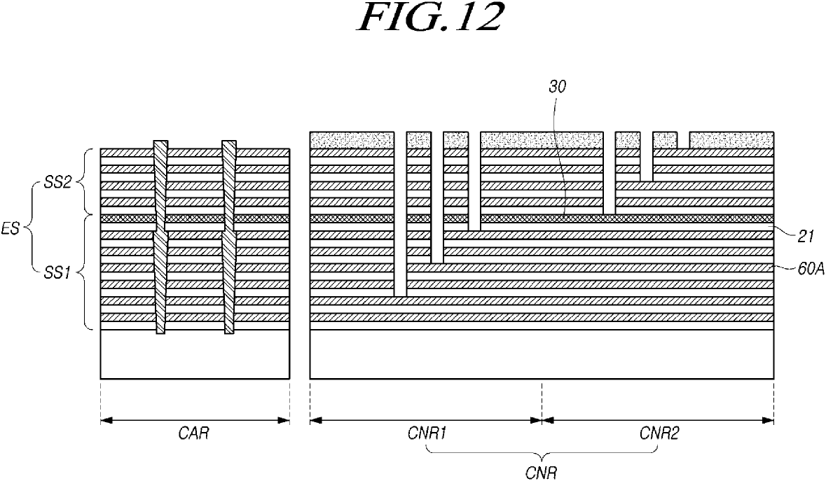

Referring to FIG. 12, a first dielectric layer 21 may be configured immediately under the etch stop layer 30. The uppermost first dielectric layer 21 of the lower structure SS1 may insulate the etch stop layer 30 from the uppermost first electrode layer 60A of the lower structure SS1.

Unlike the embodiment described above with reference to FIGS. 10A to 10G, the uppermost layer of the lower multi-layered stack ML1 may be the first dielectric layer 21, and the etch stop layer 30 may be insulated from the uppermost first electrode layer 60A of the lower structure SS1 by the first dielectric layer 21.

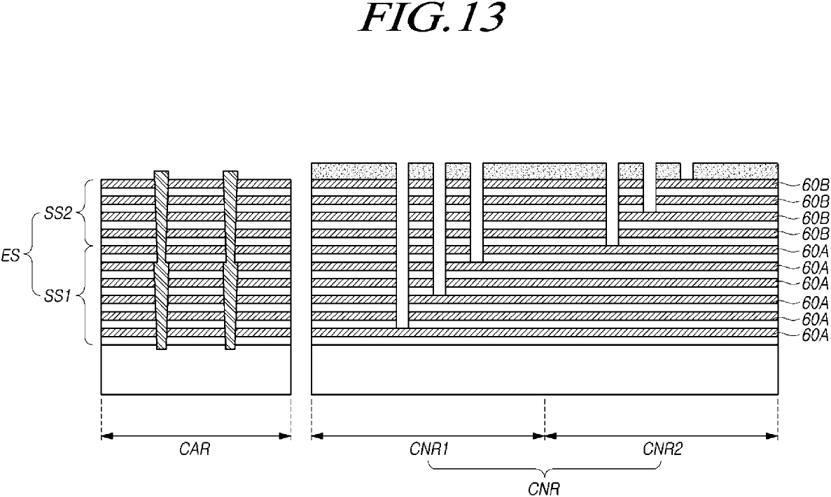

Referring to FIG. 13, a first electrode layer 60A may be configured at the uppermost part of the lower structure SS1. Unlike the embodiment of FIGS. 8A to 10G, the lower structure SS1 may not include an etch stop layer 30.

Unlike the embodiment described above with reference to FIGS. 10A to 10G, a first dielectric layer 21 may be configured immediately under the etch stop layer 30. Also, unlike the embodiment described above with reference to FIGS. 10A to 10G, after removing the first and second sacrificial layers 22 and 52, and before filling an electrode material into spaces created by the removal of the first and second sacrificial layers 22 and 52, a process of removing the etch stop layer 30 may be further performed. As a result, the electrode material may fill in spaces created by the removal of the first and second sacrificial layers 22 and 52 and the etch stop layer 30.

The uppermost first electrode layer 60A of the lower structure SS1 may be configured by the electrode material used to fill in a space created by the removal of the etch stop layer 30. The uppermost first electrode layer 60A of the lower structure SS1 may have the same thickness as the etch stop layer 30.

When the etch stop layer 30 has the same thickness as the first and second sacrificial layers 22 and 52, the uppermost first electrode layer 60A of the lower structure SS1 may have the same thickness as the other electrode layers. Consequently, the uppermost first electrode layer 60A of the lower structure SS1 may configure a word line.

Since the uppermost first electrode layer 60A of the lower structure SS1 has the same thickness as the other electrode layers, the characteristics of memory cells that are coupled to the uppermost first electrode layer 60A of the lower structure SS1 may not be different from the characteristics of memory cells which are coupled to the other electrode layers. Because reliability is not degraded when the memory cells that are coupled to the uppermost first electrode layer 60A of the lower structure SS1 are used to store data, the uppermost first electrode layer 60A of the lower structure SS1 may be configured as a word line to increase memory capacity.

According to the embodiments of the present disclosure described above, a Z-slim etching process is performed using the etch stop layer 30 as an etch end target. Accordingly, it is not necessary to precisely control process conditions such as an etch energy and an etch time in order to cause etching to be ended at a desired position, and so it is possible to improve process margins.

As aforementioned, when the requirements for the shape and size of a region to be etched in the Z-slim etching process reduce the area of the coupling region CNR, process conditions should be changed. According to the embodiments of the present disclosure, since the margin of the Z-slim etching process may be improved, even when the shape and size of a region to be etched in the Z-slim etching process are changed to reduce the area of the coupling region CNR, the Z-slim etching process may be used to configure pad portions of electrode layers with fewer process steps.

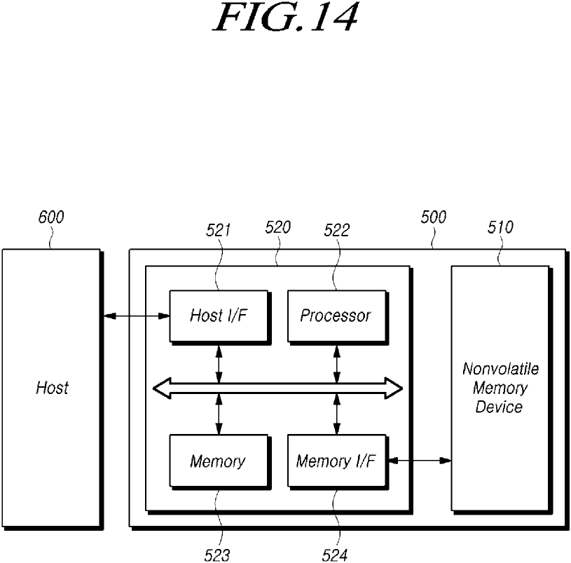

FIG. 14 is a block diagram schematically illustrating a memory system including a three-dimensional memory device in accordance with an embodiment of the present disclosure.

Referring to FIG. 14, a memory system 500 may store data to be accessed by a host 600 such as a mobile phone, an MP3 player, a laptop computer, a desktop computer, a game player, a TV, an in-vehicle infotainment system, and so forth.

The memory system 500 may be manufactured as any one of various kinds of storage devices according to the protocol of an interface that is electrically coupled to the host 600. For example, the memory system 500 may be configured as any one of various kinds of storage devices such as a solid state drive, a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a Personal Computer Memory Card International Association (PCMCIA) card type storage device, a peripheral component interconnection (PCI) card type storage device, a PCI express (PCI-E) card type storage device, a compact flash (CF) card, a smart media card, a memory stick, and so forth.

The memory system 500 may be manufactured as any one among various kinds of package types. For example, the memory system 500 may be manufactured as any one of various kinds of package types such as a package-on-package (POP), a system-in-package (SIP), a system-on-chip (SOC), a multi-chip package (MCP), a chip-on-board (COB), a wafer-level fabricated package (WFP) and a wafer-level stack package (WSP).

The memory system 500 may include a nonvolatile memory device 510 and a controller 520.

The nonvolatile memory device 510 may operate as a storage medium of the memory system 500. The nonvolatile memory device 510 may be configured by any one of various types of nonvolatile memory devices such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase change random access memory (PRAM) using a chalcogenide alloy, and a resistive random access memory (RERAM) using a transition metal compound, depending on the type of memory cells.

While FIG. 14 illustrates that the memory system 500 includes one nonvolatile memory device 510, this is only for the sake of convenience in explanation, and the memory system 500 may include a plurality of nonvolatile memory devices. The present disclosure may be applied the same to the memory system 500 including a plurality of nonvolatile memory devices. The nonvolatile memory device 510 may include memory devices according to the embodiments of the present disclosure.

The controller 520 may control general operations of the memory system 500 through driving of firmware or software loaded in a memory 523. The controller 520 may decode and drive a code type instruction or algorithm such as firmware or software. The controller 520 may be implemented in the form of hardware or in a combined form of hardware and software.

The controller 520 may include a host interface Host I/F 521, a processor 522, the memory 523 and a memory interface Memory I/F 524. Although not illustrated in FIG. 14, the controller 520 may further include an ECC (error correction code) engine that generates a parity by ECC-encoding write data provided from the host 600 and ECC-decodes read data, read from the nonvolatile memory device 510, by using the parity.

The host interface Host I/F 521 may interface the host 600 and the memory system 500 in correspondence to the protocol of the host 600. For example, the host interface Host I/F 521 may communicate with the host 600 through any one of universal serial bus (USB), universal flash storage (UFS), multimedia card (MMC), parallel advanced technology attachment (PATA), serial advanced technology attachment (SATA), small computer system interface (SCSI), serial attached SCSI (SAS), peripheral component interconnection (PCI) and PCI express (PCI-E) protocols.

The processor 522 may be configured by a micro control unit (MCU) or a central processing unit (CPU). The processor 522 may process a request transmitted from the host 600. In order to process a request transmitted from the host 600, the processor 522 may drive a code type instruction or algorithm, that is, firmware, loaded in the memory 523, and may control the internal function blocks such as the host interface Host I/F 521, the memory 523 and the memory interface Memory I/F 524 and the nonvolatile memory device 510.

The processor 522 may generate control signals for controlling the operation of the nonvolatile memory device 510, on the basis of requests transmitted from the host 600, and may provide the generated control signals to the nonvolatile memory device 510 through the memory interface Memory I/F 524.

The memory 523 may be configured by a random access memory such as a dynamic random access memory (DRAM) or a static random access memory (SRAM). The memory 523 may store firmware to be driven by the processor 522. Also, the memory 523 may store data necessary for driving the firmware, for example, metadata. Namely, the memory 523 may operate as a working memory of the processor 522.

The memory 523 may be configured to include a data buffer for temporarily storing write data to be transmitted from the host 600 to the nonvolatile memory device 510 or read data to be transmitted from the nonvolatile memory device 510 to the host 600. In other words, the memory 523 may operate as a buffer memory. The memory 523 may receive and store map data from the nonvolatile memory device 510 when the memory system 500 is booted.

The memory interface Memory I/F 524 may control the nonvolatile memory device 510 under the control of the processor 522. The memory interface Memory I/F 524 may also be referred to as a memory controller. The memory interface Memory I/F 524 may provide control signals to the nonvolatile memory device 510. The control signals may include a command, an address, an operation control signal and so forth for controlling the nonvolatile memory device 510. The memory interface Memory I/F 524 may provide data, stored in the data buffer, to the nonvolatile memory device 510, or may store data, transmitted from the nonvolatile memory device 510, in the data buffer.

The controller 520 may further include a map cache (not illustrated) that caches map data referred to by the processor 522 among map data stored in the memory 523.

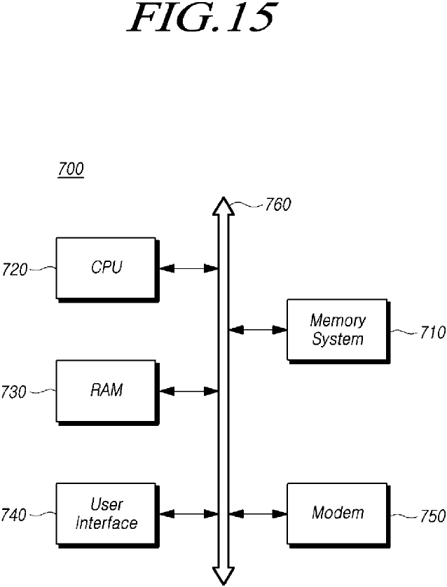

FIG. 15 is a block diagram schematically illustrating a computing system including a three-dimensional memory device in accordance with embodiments of the disclosure.

Referring to FIG. 15, a computing system 700 in accordance with an embodiment may include a memory system 710, a microprocessor (CPU) 720, a RAM 730, a user interface 740 and a modem 750 such as a baseband chipset, which are electrically coupled to a system bus 760. In the case where the computing system 700 in accordance with the embodiment is a mobile device, a battery (not shown) for supplying the operating voltage of the computing system 700 may be additionally provided. Although not shown in the drawing, it is obvious to a person skilled in the art to which the embodiment pertains that the computing system 700 in accordance with the embodiment may be additionally provided with an application chipset, a camera image processor (CIS), a mobile DRAM, and so on. The memory system 710 may configure, for example, an SSD (solid state drive/disk) that uses a nonvolatile memory to store data. Otherwise, the memory system 710 may be provided as a fusion flash memory (for example, a OneNAND flash memory).

Although the detailed description of the present invention described above has been described with reference to the embodiments of the present invention, those skilled in the art or those having ordinary skill in the art will understand that the present invention can be variously modified and changed without departing from the spirit and scope of the present invention described in the claims to be described later.

What is claimed is:

1. A method for manufacturing a three-dimensional memory device, comprising:
forming a lower multi-layered stack by alternately stacking a plurality of first dielectric layers and a plurality of first sacrificial layers on a substrate;
forming an etch stop layer on the lower multi-layered stack;
forming an upper multi-layered stack by alternately stacking a plurality of second dielectric layers and a plurality of second sacrificial layers on the etch stop layer;
forming a vertical trench by etching the upper multi-layered stack using the etch stop layer as an etch end target;
removing the etch stop layer under the vertical trench; and
forming a first stairway-shaped trench in the lower multi-layered stack under the vertical trench, and forming a second stairway-shaped trench in the upper multi-layered stack.

2. The method according to claim 1, wherein the etch stop layer is formed of a material that has an etch selectivity different from the etch selectivity of the plurality of second dielectric layers and the plurality of second sacrificial layers.

3. The method according to claim 1, wherein the etch stop layer includes at least one of polysilicon, tungsten and TiN.

4. The method according to claim 1, further comprising, after the forming of the first and second stairway-shaped trenches,
replacing the plurality of first sacrificial layers and the plurality of second sacrificial layers with an electrode material.

5. The method according to claim 1, further comprising, after the forming of the first and second stairway-shaped trenches,
replacing the plurality of first sacrificial layers, the plurality of second sacrificial layers and the etch stop layer with an electrode material.

6. The method according to claim 1, wherein
an uppermost layer of the lower multi-layered stack is a first sacrificial layer, and
the etch stop layer has a thickness that is thinner than the plurality of first sacrificial layers and the plurality of second sacrificial layers.

7. The method according to claim 1, further comprising, before the forming of the upper multi-layered stack,
forming a lower channel hole that passes through the etch stop layer and the lower multi-layered stack.

8. The method according to claim 7, further comprising, after the forming of the upper multi-layered stack,
forming an upper channel hole, which communicates with the lower channel hole, by etching the upper multi-layered stack; and
forming a cell plug in the lower channel hole and the upper channel hole.

9. A three-dimensional memory device comprising:
a lower structure including a plurality of first dielectric layers and a plurality of first electrode layers that are alternately stacked on a substrate, and having an uppermost layer that is configured by one of the first electrode layers and has a thickness that is different from the thickness of an etch stop layer and the other underlying first electrode layers;
an upper structure including a plurality of second dielectric layers and a plurality of second electrode layers, which are alternately stacked on the lower structure;
a vertical trench exposing the lower structure by passing through the upper structure;
a first stairway-shaped trench, configured in the lower structure under the vertical trench, that communicates with the vertical trench; and
a second stairway-shaped trench configured in the upper structure.

10. The three-dimensional memory device according to claim 9, wherein
a first electrode layer is configured immediately under the etch stop layer, and
the first electrode layer immediately under the etch stop layer configures a dummy word line.

11. The three-dimensional memory device according to claim 9, wherein a first electrode layer, as an uppermost layer of the lower structure, configures a dummy word line.

12. The three-dimensional memory device according to claim 9, further comprising:
a lower channel hole extending to the substrate by passing through the lower structure;
an upper channel hole communicating with the lower channel hole by passing through the upper structure; and
a cell plug configured in the lower channel hole and the upper channel hole.

13. A method for manufacturing a three-dimensional memory device, comprising:
forming a lower multi-layered stack by alternately stacking a plurality of first dielectric layers and a plurality of first sacrificial layers on a substrate;
forming an etch stop layer on the lower multi-layered stack;
forming an upper multi-layered stack by alternately stacking a plurality of second dielectric layers and a plurality of second sacrificial layers on the etch stop layer;
forming a plurality of first vertical holes by etching the upper multi-layered stack using the etch stop layer as an etch end target;
removing the etch stop layer under the plurality of first vertical holes; and
forming a plurality of second vertical holes, which extend downward from the plurality of first vertical holes, in the lower multi-layered stack, and forming a plurality of third vertical holes in the upper multi-layered stack.

14. The method according to claim 13, wherein the etch stop layer is formed of a material that has an etch selectivity different from the plurality of second dielectric layers and the plurality of second sacrificial layers.

15. The method according to claim 13, wherein the etch stop layer includes at least one of polysilicon, tungsten and TiN.

16. The method according to claim 13, further comprising, after the forming of the first, second and third vertical holes,
replacing the plurality of first sacrificial layers and the plurality of second sacrificial layers with an electrode material.

17. The method according to claim 13, further comprising, after the forming of the first, second and third vertical holes,
replacing the plurality of first sacrificial layers, the plurality of second sacrificial layers and the etch stop layer with an electrode material.

18. The method according to claim 13, wherein
an uppermost layer of the lower multi-layered stack is a first sacrificial layer, and
the etch stop layer has a thickness that is thinner than the plurality of first sacrificial layers and the plurality of second sacrificial layers.
